(19) United States
(12) Patent Application Publication
(10) Pub. No.: US 2026/0163561 A1
(43) Pub. Date: Jun. 11, 2026

(54) SEMICONDUCTOR DEVICE AND METHOD OF MANUFACTURING THE SAME

(71) Applicant: RENESAS ELECTRONICS CORPORATION, Tokyo (JP)

(72) Inventors: Masahiko KURAUCHI, Tokyo (JP); Toshiyuki MARUYAMA, Tokyo (JP); Shinnosuke FUJITA, Tokyo (JP)

(21) Appl. No.: 19/413,242

(22) Filed: Dec. 9, 2025

(30) Foreign Application Priority Data
Dec. 11, 2024 (JP) 2024-216428

(51) Int. Cl. H03K 5/131; H03K 5/135; H03K 5/00

(52) U.S. Cl. CPC H03K 5/131; H03K 5/135; H03K 2005/00084

(57) ABSTRACT

To provide a semiconductor device and its manufacturing method capable of designing the intended delay with high precision using fewer steps. The manufacturing method of the semiconductor device disclosed herein arranges multiple circuits on a plane and connects wiring to each, comprising: a placement step of arranging a digital circuit that operates based on timing signals and a delay circuit configured with multiple delay paths having different input/output delay amounts, where one of the multiple delay paths can be selected by a selection signal; a wiring step of connecting the output of the delay circuit so that it becomes the timing signal of the digital circuit; and a delay adjustment step of selecting one of the multiple delay paths by connecting a predetermined voltage as the selection signal, and selecting the delay amount so that the input/output timing of the digital circuit meets predetermined conditions.

### CROSS-REFERENCE TO RELATED APPLICATIONS

The disclosure of Japanese Patent Application No. 2024-216428 filed on December 11, 2024, including the specification, drawings and abstract is incorporated herein by reference in its entirety.

### BACKGROUND

This disclosure relates to a semiconductor device and its manufacturing method, particularly to a semiconductor device and its manufacturing method configured to arrange multiple circuits on a plane and connect wiring to each.

In semiconductor devices, the miniaturization of the manufacturing process and the reduction of operating power supply voltage are advancing. As miniaturization and low voltage progress, the impact of clock timing defects due to wiring delay in semiconductor devices becomes significant.

The timing between a semiconductor device and an external device is referred to as AC timing (Analog Current Timing). Verification of signals via external devices may be necessary as part of AC timing verification. Therefore, when verifying operation, it is necessary to consider the delay of signals via external devices.

As the manufacturing process becomes more miniaturized, the operating frequency of semiconductor devices increases, creating a difference in operating speed with external devices. As a method to reduce the delay difference between semiconductor devices and external devices, a method of inserting a delay value to pre-slow the signal transfer can be mentioned. The delay value can be on the order of several tens of nanoseconds at most.

There are disclosed techniques listed below.

[Patent Document 1] Japanese Unexamined Patent Application Publication No. 2010-146047

Patent Document 1 discloses a semiconductor device that resolves clock timing defects by inserting a buffer circuit to adjust the delay time. Additionally, Patent Document 1 discloses providing a cell occupancy rate check unit to calculate the congestion level of a predetermined area to prevent the buffer circuit from being locally concentrated.

### SUMMARY

When using a tool to automatically improve timing violation locations for delay value insertion, as mentioned above, circuits may become locally concentrated. When circuits and wiring are locally concentrated, it can cause EM errors (Electro Migration Errors), so the delay is manually resolved by inserting circuits.

To manually resolve delays, it becomes necessary to sequentially correct locations where AC timing defects occur in a once-laid-out circuit diagram. Since power analysis needs to be performed with each layout change, there is a challenge of increased rework.

Other problems and novel features will become apparent from the description herein and from the accompanying drawings.

According to one embodiment, the manufacturing method of the semiconductor device of this disclosure involves arranging a delay circuit capable of selecting one of multiple delay paths by a selection signal, connecting the output of the delay circuit to become the timing signal of a digital circuit, and selecting one of the multiple delay paths by connecting a predetermined voltage as the selection signal, selecting the delay amount so that the input/output timing of the digital circuit meets predetermined conditions. Other features will be described in detail below.

This disclosure enables the provision of a semiconductor device and its manufacturing method capable of designing the assumed delay with high precision with fewer steps.

### BRIEF DESCRIPTION OF THE DRAWINGS

FIG. 1A is a layout of the semiconductor device of this disclosure.

FIG. 1B is a configuration diagram of the delay HM of this disclosure.

FIG. 1C is a plan view of the layout of the semiconductor device of this disclosure.

FIG. 2 is a flowchart showing the manufacturing method of the semiconductor device of this disclosure.

FIG. 3A is a first diagram explaining the adjustment of output delay in the semiconductor device of this disclosure.

FIG. 3B is a second diagram explaining the adjustment of output delay in the semiconductor device of this disclosure.

FIG. 3C is a third diagram explaining the adjustment of output delay in the semiconductor device of this disclosure.

FIG. 3D is a layout explaining the adjustment of output delay in the semiconductor device of this disclosure.

FIG. 4A is a first diagram explaining the adjustment of input delay in the semiconductor device of this disclosure.

FIG. 4B is a second diagram explaining the adjustment of input delay in the semiconductor device of this disclosure.

FIG. 4C is a third diagram explaining the adjustment of input delay in the semiconductor device of this disclosure.

FIG. 4D is a layout explaining the adjustment of input delay in the semiconductor device of this disclosure.

FIG. 5A is a first diagram explaining the switching of delay values in the semiconductor device of this disclosure.

FIG. 5B is a second diagram explaining the switching of delay values in the semiconductor device of this disclosure.

FIG. 5C is a third diagram explaining the switching of delay values in the semiconductor device of this disclosure.

FIG. 6A is a diagram explaining a first example of the switching of delay values in the semiconductor device of this disclosure.

FIG. 6B is a diagram explaining a second example of the switching of delay values in the semiconductor device of this disclosure.

FIG. 7A is a diagram explaining a first example of the switching of the delay HM in the semiconductor device of this disclosure.

FIG. 7B is a diagram explaining a second example of the switching of the delay HM in the semiconductor device of this disclosure.

FIG. 7C is a diagram explaining a third example of the switching of the delay HM in the semiconductor device of this disclosure.

FIG. 7D is a diagram explaining a fourth example of the switching of the delay HM in the semiconductor device of this disclosure.

FIG. 7E is a diagram explaining a fifth example of the switching of the delay HM in the semiconductor device of this disclosure.

FIG. 8A is a first diagram of a first related semiconductor device.

FIG. 8B is a second diagram of a first related semiconductor device.

FIG. 8C is a third diagram of a first related semiconductor device.

FIG. 9A is a first layout diagram of a second related semiconductor device.

FIG. 9B is a second layout diagram of a second related semiconductor device.

FIG. 9C is a third layout diagram of a second related semiconductor device.

### DETAILED DESCRIPTION

Hereinafter, embodiments of the present disclosure will be described in detail with reference to the drawings. In the specification and the drawings, the same or corresponding components are denoted by the same reference numerals, and repetitive descriptions thereof may be omitted. In the drawings, for convenience of description, the configuration may be omitted or simplified. Also, at least some of the embodiments may be arbitrarily combined with each other.

### <First Embodiment>

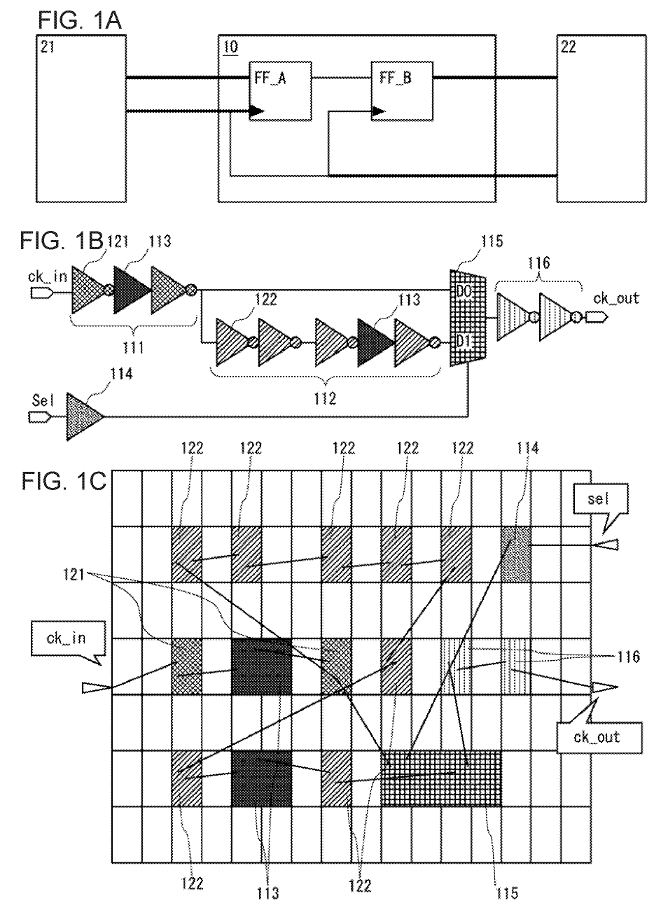

FIG. 1A is a diagram showing the layout of the semiconductor device 10 of the present disclosure before inserting the delay HM (Hard Macro), which is a delay circuit. As shown in FIG. 1A, semiconductor device 10 is connected to an external device 21 located upstream and an external device 22 located downstream. Semiconductor device 10 includes multiple circuits internally. In the configuration example shown in FIG. 1A, semiconductor device 10 is provided with two flip-flop circuits FF_A and FF_B, which are digital circuits.

In the manufacturing method of the semiconductor device of the present disclosure, multiple circuits are arranged on a plane, and wiring is connected to each. Therefore, using the delay HM, which is a circuit block incorporated as hardware, defects in AC timing (Analog Current Timing) are resolved. The semiconductor device of the present disclosure implements the delay HM shown in FIG. 1B for circuit design data, which is IP (Intellectual Property) predicted to have difficulty converging AC timing.

FIG. 1B is a diagram showing the configuration of the delay HM provided in the semiconductor device 10. A timing signal to add delay is input as an input signal to the input terminal ck_in. The input signal is output to the second circuit 112 and/or the fifth circuit 115 via the first circuit 111. The first circuit 111 includes multiple inverter circuits 121. The second circuit 112 includes multiple inverter circuits 122. Therefore, the delay HM includes multiple signal paths. The first circuit 111 and the second circuit 112 each implement delay values corresponding to the number of stages of the inverter circuits. Buffer circuits are also referred to as delay elements.

Furthermore, semiconductor device 10 includes a fourth circuit 114 that outputs a selection signal and a fifth circuit 115, which is a selector circuit operating based on the timing signal. The fifth circuit 115 receives the selection signal and the timing signal output from the first circuit 111, and adjusts the delay determined by the signal path. The selector circuit allows switching of the delay value with the selector.

For example, if 0 is input as the selection signal to the selector circuit, it switches to the D0 path that does not pass through the second circuit 112, and if 1 is input as the selection signal, it switches to the D1 path that passes through the second circuit 112. Since the delay value is determined by the number of stages of the delay elements, for example, in the D0 path, it can be delayed by the number of stages of the delay elements in the first circuit 111. Also, in the D1 path, it can be delayed by the number of stages of the delay elements in both the first circuit 111 and the second circuit 112.

Therefore, the delay HM is configured to have multiple delay paths with different input/output delay amounts, and one of the multiple delay paths can be selected by the selection signal. Also, multiple delay HMs may be arranged. The voltage connected as the selection signal in each delay circuit may be set individually.

The signal output from the fifth circuit 115 is output from the output terminal ck_out via the sixth circuit 116. The flip-flop circuit FF_B, which is a digital circuit, operates based on the timing of the delay signal and outputs the output signal to the external device 22.

FIG. 1C is a plan view of the layout of the semiconductor device 10. The first circuit 111 to the sixth circuit 116 are configured as blocks forming a rectangular shape in plain view. For example, the first circuit 111 and the second circuit 112 can arbitrarily change connections by the number of stages of the required inverter circuits. Also, the positions of the input terminal ck_in and the output terminal ck_out are fixed on the block. The input terminal ck_in and the output terminal ck_out are arranged on the same line parallel to any side of the rectangular shape.

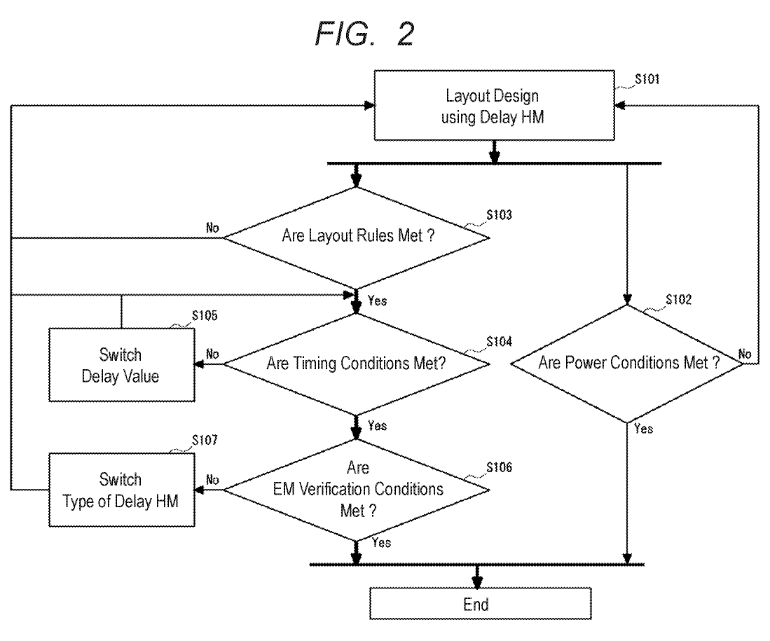

FIG. 2 is a flowchart showing the manufacturing method of semiconductor device 10 of the present disclosure. First, the layout of the semiconductor device 10 is designed using the delay HM (S101). The layout design includes at least the placement process of arranging the delay HM.

After the layout design, power analysis (S102) to verify whether the power conditions are met and verification (S103) to check whether the layout rules are met are performed in parallel. If the layout rules are not met, the layout design is performed again. If the layout rules are met, the process proceeds with the subsequent steps.

First, verify whether the timing conditions are met (S104). If the timing conditions are met, proceed to the subsequent steps. If the timing conditions are not met, switch the delay value to the extent that the timing conditions can be met (S105). Specifically, perform the wiring process to connect so that the output of the delay circuit becomes the timing signal of the digital circuit. Then, by connecting a predetermined voltage as a selection signal, select one of the multiple delay paths, and perform the delay adjustment process to select the delay amount so that the input/output timing of the digital circuit matches the predetermined conditions. The switching of the delay value at the timing violation point can be done automatically using a tool or manually by creating a command.

Once the timing conditions are met, verify whether the EM (Electro Migration) error verification conditions are met (S106). If the EM verification conditions are not met, switch the type of delay HM to meet the EM verification conditions (S107). That is, perform the characteristic adjustment process to change the number of semiconductor elements constituting the delay path while maintaining the delay amount of the delay circuit to meet the predetermined EM characteristics. The switching of the type of delay HM at the EM verification violation point can be done automatically using a tool or manually by creating a command. If the EM verification conditions are met, the process ends.

In the manufacturing method of semiconductor devices in related technical fields, design changes due to timing violation points were performed sequentially, resulting in many reworks. On the other hand, the manufacturing method of the semiconductor device of the present disclosure is a design using delay HM, so it can preemptively address issues. Therefore, by using delay HM, issues are mitigated, and since there are fewer reworks, the design man-hours can be reduced.

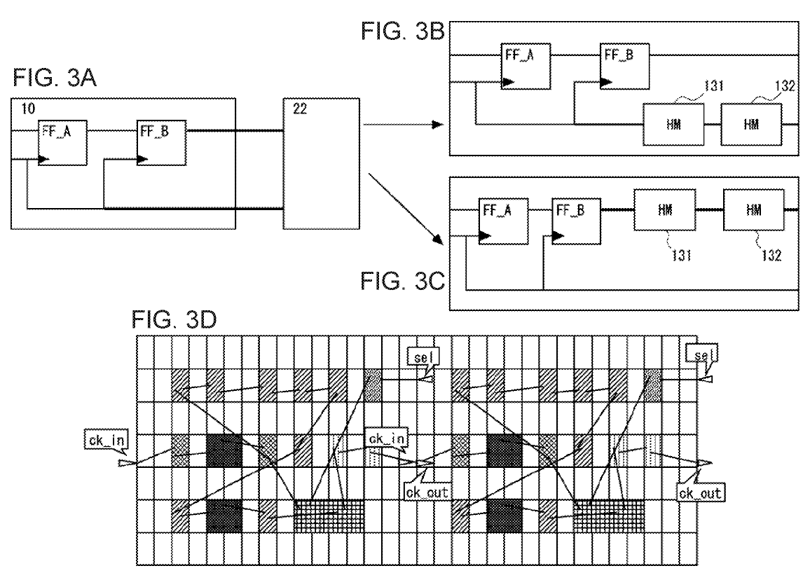

FIGS. 3A to 3D are diagrams explaining the adjustment of delay when outputting a signal to the external device 22 located downstream. In this case, timing violations occur in the clock line of the external output and in the signal from the flip-flop FF_B to the external output.

To address the timing violation in the clock line of the external output, as shown in FIG. 3B, a layout is pre-created to arrange the delay HMs 131 and 132 in parallel upstream of FF_B. The configuration of delay HMs 131 and 132 is as shown in FIG. 2B. The delay value in the second circuit 112 provided in delay HMs 131 and 132 is inserted into the clock line. This resolves the timing violation in the clock line of the external output.

To address the timing violation in the signal from the flip-flop FF_B to the external output, as shown in FIG. 3C, a layout is pre-created to arrange the delay HMs 131 and 132 in parallel downstream of FF_B. The delay value in the second circuit 112 provided in delay HMs 131 and 132 is inserted into the data line. This resolves the timing violation in the signal from the flip-flop FF_B to the external output.

Also, the delay HMs 131 and 132 are configured as blocks forming a rectangular shape and are arranged on the same line parallel to any side of the rectangular shape. Therefore, as shown in FIG. 3D, by arranging the delay HMs 131 and 132 in parallel, the pin height can be aligned.

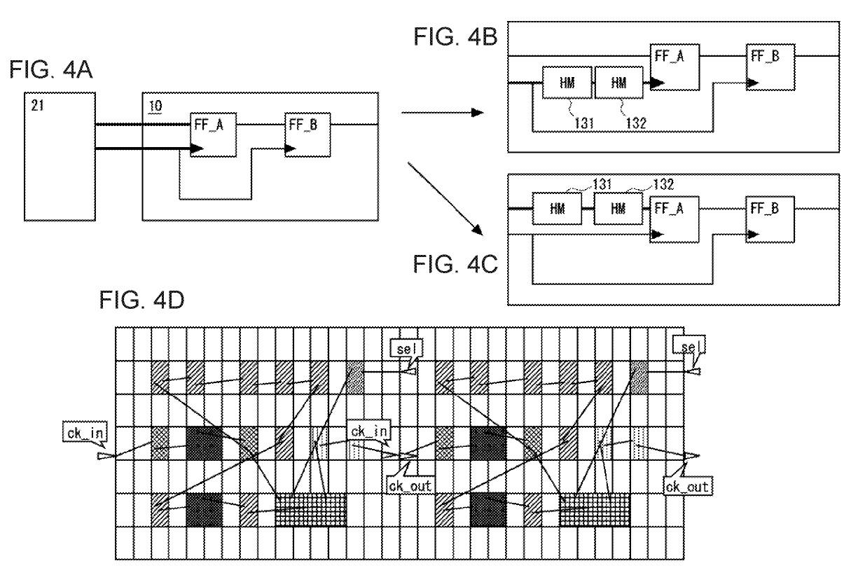

FIGS. 4A to 4D are diagrams explaining the adjustment of delay when a signal is input from the external device 21 located upstream. In this case, timing violations occur in the clock line of the external input and in the signal from the external device 21 to the flip-flop FF_A.

To address the timing violation in the clock line of the external input, as shown in FIG. 4B, a layout is pre-created to arrange the delay HMs 131 and 132 in parallel upstream of FF_A in the clock line. The configuration of delay HMs 131 and 132 is as shown in FIG. 2B. The delay value in the second circuit 112 provided in delay HMs 131 and 132 is inserted into the clock line. This resolves the timing violation in the clock line of the external input.

To address the timing violation in the signal from the external device 21 to the flip-flop FF_A, as shown in FIG. 4C, a layout is pre-created to arrange the delay HMs 131 and 132 in parallel upstream of FF_A in the data line. The delay value in the second circuit 112 provided in delay HMs 131 and 132 is inserted into the data line. This resolves the timing violation in the signal from the external device 21 to the flip-flop FF_A.

Additionally, the delays HM131 and HM132 are composed of blocks forming a rectangular shape and are arranged on the same line parallel to any side of the rectangle. Therefore, as shown in FIG. 4D, by arranging the delays HM131 and HM132 in parallel, the height of the pins can be aligned.

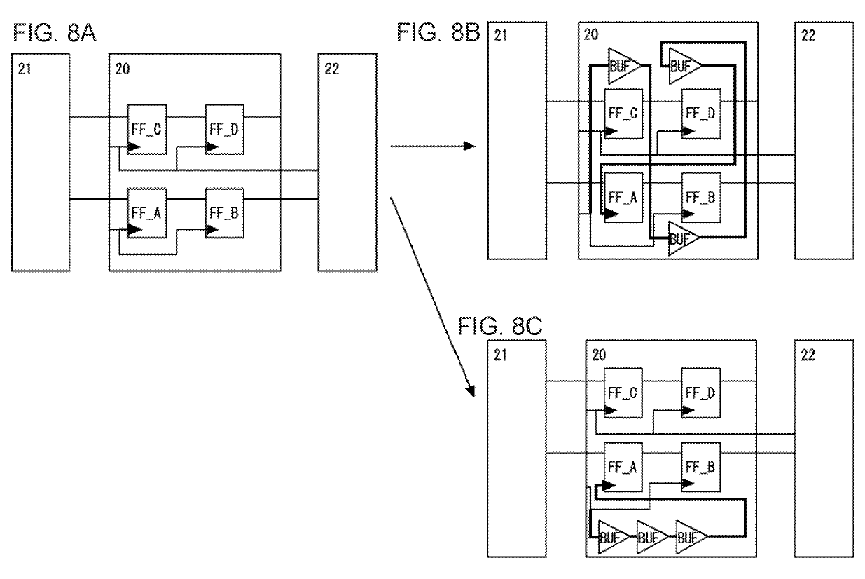

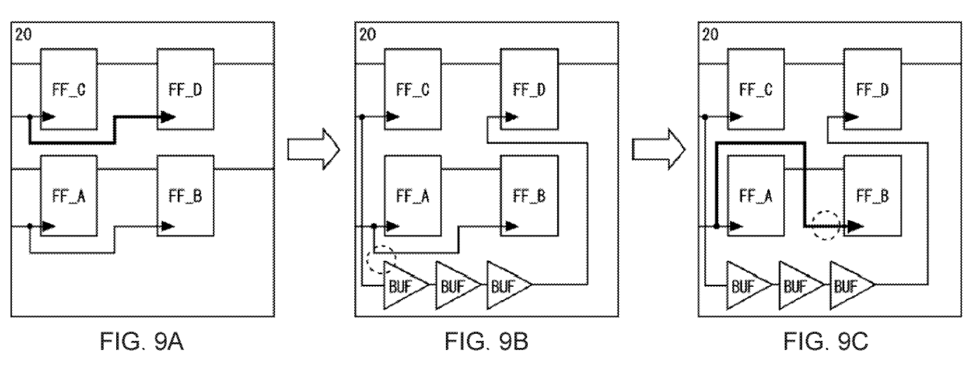

As a comparative example, consider the case of inserting a buffer circuit BUF into a semiconductor device 20, whose layout has already been determined, using FIGS. 8A to 8C and FIGS. 9A to 9C. FIGS. 8A and 9A show a semiconductor device 20 having four flip-flops FF_A to FF_D. If a delay of several tens of nanoseconds is provided after the wiring process in this semiconductor device 20, the wiring to bypass the existing circuit may complicate the design, potentially resulting in a delay value greater than intended (see FIGS. 8B and 8C).

Furthermore, as the process becomes more refined, the delay value per element decreases, leading to a significant increase in the number of buffer circuits BUF to be inserted. Consequently, this results in an increase in the number of elements required to achieve the desired delay value, as well as an increase in the workload during the design phase.

Additionally, consider the case where a buffer circuit BUF can be inserted into the clock line of flip-flop FF_D after the wiring process. As indicated by the dotted line in FIG. 9B, a design rule violation may occur between the newly inserted buffer circuit BUF, the wiring, and the existing wiring. Even if the clock line of flip-flop FF_D is rewired to resolve the design rule violation in FIG. 9B, the delay value may increase, causing previously met timing points to become erroneous.

Moreover, since power analysis is conducted in parallel with timing design in backend design, accurate analysis cannot be performed until the number and types of cells to be used are determined. Therefore, there is a problem in estimating the leakage amount due to delay insertion. Furthermore, the concentration of delay insertion can lead to an increased likelihood of EM errors.

The semiconductor device and its manufacturing method disclosed herein can overcome the above-mentioned challenges and issues.

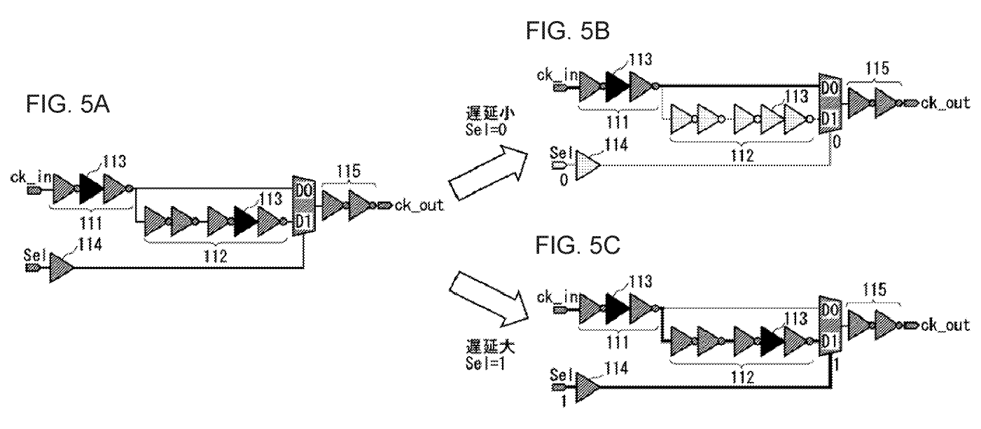

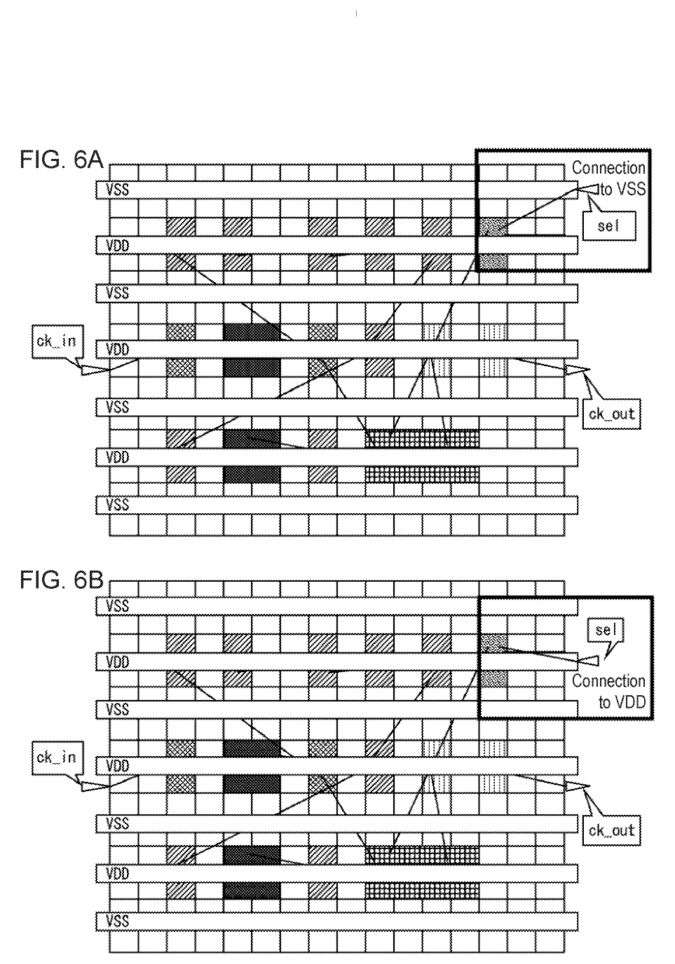

Next, the method for setting a fixed value in the fifth circuit 115, which is a digital circuit, will be described with reference to FIGS. 5 and 6. Note that the description of overlapping parts with FIGS. 1B and 1C in the configuration of the delay HM shown in FIGS. 5 and 6 is omitted. The delay HM shown in FIG. 5A is supplied with a power supply voltage and a ground voltage. The selection of the delay path may be performed by connecting either the power supply voltage or the ground voltage as a selection signal (see FIGS. 5B and 5C). In other words, the switching of the delay value is performed by switching from the power supply voltage to the ground voltage or from the ground voltage to the power supply voltage. As shown in FIGS. 6A and 6B, since the delay value can be switched only by changing the connection from VDD to VSS, the impact on resolving timing violations is minimal.

In addition, elements (Tie-High, Tie-Low) for fixing the signal value to High or Low may be used for switching. Furthermore, it is possible to automate the switching by recognizing the delay HM using an EDA (Electronic Design Automation) tool and obtaining timing verification results.

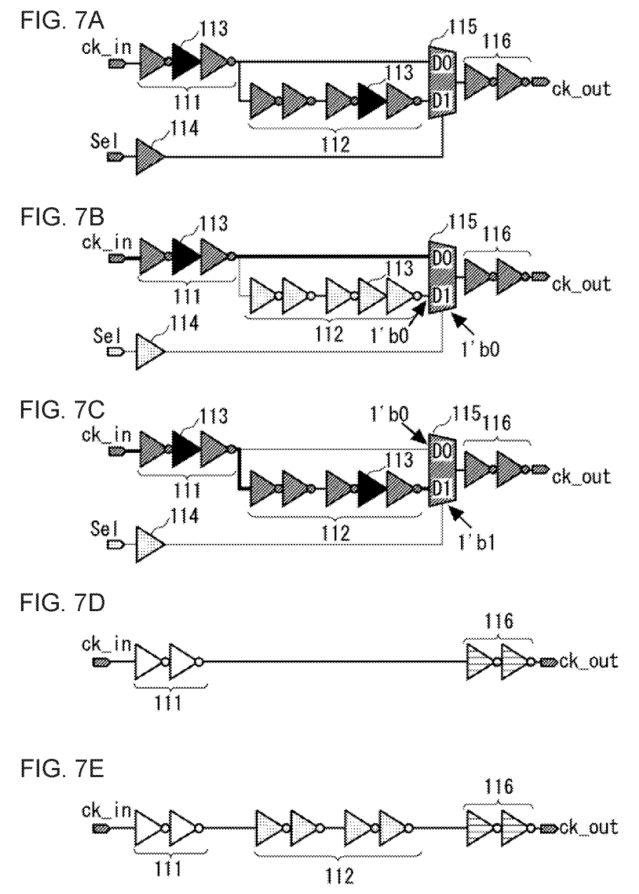

As described above, countermeasures against EM errors due to delay HM are implemented, but countermeasures for EM errors caused by other factors of the semiconductor device 10 will be described with reference to FIGS. 7A to 7E. Note that the description of overlapping parts with FIG. 1B in the configuration of the delay HM shown in FIGS. 7A to 7E is omitted.

FIG. 7A shows the standard delay HM of the present disclosure as shown in FIG. 1B. FIG. 7B shows a delay HM for deleting the second circuit 112 and the fourth circuit 114 that outputs the selection signal. FIG. 7C shows a delay HM for deleting the path directly connecting from the first circuit 111 to the fifth circuit and the fourth circuit 114 that outputs the selection signal. FIG. 7D shows a delay HM in which the second circuit 112, the fourth circuit 114 that outputs the selection signal, and the fifth circuit 115 are deleted at the layout design stage. FIG. 7E shows a delay HM in which the path directly connects from the first circuit 111 to the fifth circuit and the fourth circuit 114 that outputs the selection signal, and the fifth circuit 115 are deleted at the layout design stage.

By preparing multiple types of delay HM in this way, it is possible to replace them with delay HM without a selector with fewer cells (see FIGS. 7D and 7E), thereby resolving EM errors.

Although the invention made by the inventors has been specifically described based on the embodiment, it is needless to say that the present disclosure is not limited to the embodiment already described, and various modifications can be made without departing from the gist thereof.

What is claimed is:

1. A method for manufacturing semiconductor device that arranges a plurality of circuits on a design plane and connects wiring to each, comprising:
(a) arranging a digital circuit that operates based on timing signals;
(b) arranging a delay circuit comprising multiple delay paths having different input/output delay amounts, where one of the multiple delay paths can be selected by a selection signal;
(c) connecting an output terminal of the delay circuit with an input terminal of the digital circuit as the timing signal of the digital circuit; and
(d) selecting one of the multiple delay paths by connecting a predetermined voltage as the selection signal, and selecting the delay amount so that the input/output timing of the digital circuit meets predetermined conditions.

2. The method according to claim 1,
wherein the delay circuit includes a power supply voltage and a ground voltage, and
wherein the selection of the delay path is performed by connecting either the power supply voltage or the ground voltage as the selection signal.

3. The method according to claim 1,
wherein the semiconductor device comprises a plurality of the delay circuit, and
wherein the signal path in each delay circuit has a voltage individually set for connection as the selection signal.

4. The method according to claim 1, wherein the (d) selecting step further comprising:
(d1) changing the number of semiconductor elements constituting the delay path while maintaining the delay amount of the delay circuit, so that the semiconductor device meets predetermined EM (Electro Migration) characteristics.

5. The method according to claim 1,
wherein the digital circuit and the delay circuit have rectangular shapes in plain view in the design plane, and
wherein the positions of input and output terminals of the delay circuit are fixed on any of the rectangular shapes.

6. The method according to claim 5, wherein the input and output terminals of the delay circuit are arranged on the same line parallel to any side of the rectangular shapes.

7. A semiconductor device comprising:
a delay circuit configured to input an input signal and to output a delay signal which is generated by adding a predetermined delay to the input signal; and
a digital circuit configured to operate based on the timing of the delay signal and to output an output signal,
wherein the delay circuit includes multiple delay elements and a selector circuit configured to select any of multiple signal paths with different connection stages of the delay elements, and
wherein the output timing of the output signal of the digital circuit is adjusted by the delay determined by the signal path selected by the selector circuit.

8. The semiconductor device according to claim 7,
wherein the delay circuit further comprises a power supply voltage and a ground voltage, and
wherein the selection by the selector circuit is performed by connecting either the power supply voltage or the ground voltage as the selection signal.

9. The semiconductor device according to claim 8, further comprising a plurality of the delay circuits, and
wherein the signal path in each delay circuit has a voltage individually set for connection as the selection signal.
